(19) United States
(12) Patent Application Publication
(10) Pub. No.: US 2026/0344157 A1
(43) Pub. Date: Oct. 29, 2026

(54) LED COLOR MIXER

(71) Applicant: CreeLED, Inc., Durham, NC (US)

(72) Inventors: Michael Check, Holly Springs, NC (US); David Suich, Durham, NC (US); Joseph G. Sokol, Durham, NC (US); Colin Blakely, Raleigh, NC (US); Steven Wuester, Salemburg, NC (US)

(21) Appl. No.: 19/191,567

(22) Filed: Apr. 28, 2025

(51) Int. Cl. H10H 29/85; H10H 29/851; H10H 29/853; H10H 29/854; H10H 29/855; H10H 29/856; H10W 90/00

(52) U.S. Cl. CPC H10H 29/8508; H10H 29/8514; H10H 29/8516; H10H 29/855; H10H 29/856; H10W 90/00; H10H 29/853; H10H 29/854

(57) ABSTRACT

Light-emitting diode (LED) devices, and more particularly, LED color mixers in LED packages are disclosed. The LED package includes two or more LED chips of different colors and a color mixer that provides a chamber in which the different color light from the two or more LED chips mixes via specular and diffuse reflection and exits the LED package. The disclosed LED package is characterized in that the light exits the LED package opposite the side of the LED package from which the light is emitted by the two or more LED chips, passing through a lead frame on which the LED chips are mounted. The LED color mixer of the disclosed LED package solves problems related to die attach compliance and complete color mixing in a small mass producible package.

### FIELD OF THE DISCLOSURE

The present disclosure relates to light-emitting diode (LED) devices, and more particularly to an LED color mixer in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

LED packages that contain more than one LED chip, particularly LED packages with different colored LED chips can have far field patterns (FFPs) that have different color intensities depending on the angle at which the LED package is viewed. This is detrimental to the color uniformity of LED displays and other applications as the color is observed to change with viewing angle.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to an LED color mixer in LED packages. The LED package includes two or more LED chips of different colors and a color mixer that provides a chamber in which the different color light from the two or more LED chips mixes via specular and diffuse reflection and exits the LED package. The disclosed LED package is characterized in that the light exits the LED package opposite the side of the LED package from which the light is emitted by the two or more LED chips, passing through a lead frame on which the LED chips are mounted. The LED color mixer of the disclosed LED package solves problems related to die attach compliance and complete color mixing in a small mass producible package.

In one aspect, an LED package includes a lead frame and a plurality of LED chips mounted on a first side of the lead frame that emit light in a first orientation. The LED package also includes a color mixer comprising a cavity in which the light emitted by the plurality of LED chips mixes, wherein the light is emitted from the color mixer via an aperture proximate to the second side of the lead frame opposite the first side in a second orientation opposite the first orientation. In an embodiment, the light emitted from the color mixer passes through gaps in the lead frame. In an embodiment, the LED package further includes a housing in which the lead frame, plurality of LED chips and color mixer are housed. In an embodiment, the LED package further includes a lens fixed to the housing that receives light from the aperture and emits the light after passing through the lens. In an embodiment, a width of the aperture is equal to a width of the cavity of the color mixer. In an embodiment, the color mixer comprises a reflective layer. In an embodiment, the reflective layer comprises at least one of a specular reflective layer or a diffuse reflective layer. In an embodiment, the color mixer is in a shape that is at least one of conical, prismatic, pyramidical, spherical, elliptical, cuboid, or cylindrical. In an embodiment, the cavity comprises at least one of air, vacuum, or silicone. In an embodiment, the plurality of LED chips include at least one red LED chip, at least one blue LED chip, and at least one green LED chip.

In another aspect, an LED package includes a housing, an LED frame mounted in the housing, a plurality of LED chips mounted on a first side of the lead frame that emit light in a first orientation, and a color mixer mounted within the housing that comprises a cavity surrounded by a reflective layer in which the light emitted by the plurality of LED chips mixes, wherein the light is emitted from the color mixer via an aperture proximate to the second side of the lead frame opposite the first side in a second orientation opposite the first orientation. In an embodiment, the light emitted from the color mixer passes through gaps in the lead frame. In an embodiment, the LED package further includes a lens fixed to the housing that receives light from the aperture and emits the light after passing through the lens. In an embodiment, a width of the aperture is equal to a width of the cavity of the color mixer. In an embodiment, the color mixer comprises a reflective layer. In an embodiment, the reflective layer comprises at least one of a specular reflective layer or a diffuse reflective layer. In an embodiment, the color mixer is in a shape that is at least one of conical, prismatic, pyramidical, spherical, elliptical, cuboid, or cylindrical. In an embodiment, the cavity comprises at least one of air, vacuum, or silicone.

In another aspect, a lighting device includes a board, and a LED package mounted on the board. The LED package includes a lead frame, a plurality of LED chips mounted on a first side of the lead frame that emit light in a first orientation, and a color mixer comprising a cavity in which the light emitted by the plurality of LED chips mixes, wherein the light is emitted from the color mixer via an aperture proximate to the second side of the lead frame opposite the first side in a second orientation opposite the first orientation. In an embodiment, the reflective layer of the color mixer comprises at least one of a specular reflective layer or a diffuse reflective layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package with a color mixer according to an embodiment of the present disclosure.

FIG. 2 is a cross-sectional view of another LED package with a different shaped color mixer according to an embodiment of the present disclosure.

FIG. 3 is a top-down view of a lead frame with separate electrodes with a plurality of LED chips according to an embodiment of the present disclosure.

FIG. 4 is a top-down view of a lead frame with a common electrode with a plurality of LED chips according to an embodiment of the present disclosure.

FIG. 5 is a cross-sectional view of the LED package of FIG. 2 with an additional lens according to an embodiment of the present disclosure.

FIGS. 6A-H are views of different shapes of color mixers according to embodiments of the present disclosure.

FIGS. 7A and 7B are graphs showing the intensity of different colors at different viewing angles for a state of the art color mixer and the color mixer as disclosed herein according to principles of the present disclosure.

FIG. 8 is a schematic diagram of a portion of an LED device, such as a display screen including a large number of LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to an LED color mixer in LED packages. The LED package includes two or more LED chips of different colors and a color mixer that provides a chamber in which the different color light from the two or more LED chips mixes via specular and diffuse reflection and exits the LED package. The disclosed LED package is characterized in that the light exits the LED package opposite the side of the LED package from which the light is emitted by the two or more LED chips, passing through a lead frame on which the LED chips are mounted. The LED color mixer of the disclosed LED package solves problems related to die attach compliance and complete color mixing in a small mass producible package.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group Ill nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to multiple-chip LED packages where multiple LED chips are arranged within a common package. For multiple-chip examples, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Cai-x-ySrxEuyAISiN3) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, polyamide, polyimide, polyethylene terephthalate, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. Encapsulant materials may also form lenses that direct light in desired emission directions and/or patterns. In certain embodiments, one or more lumiphoric materials, such as phosphor particles, may be integrated or otherwise embedded within the encapsulant material.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

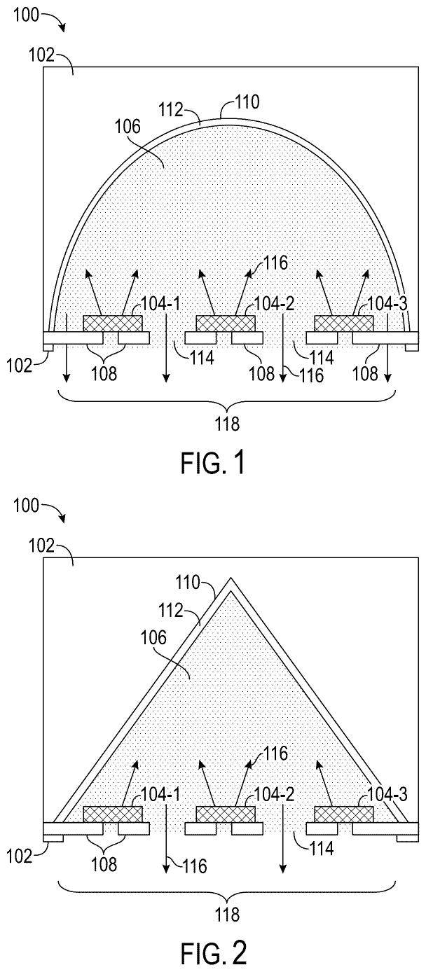

FIG. 1 is a cross-sectional view of a light-emitting diode (LED) package with a color mixer according to an embodiment of the present disclosure.

FIG. 1 depicts an LED package 100 that includes a housing 102 with a lead frame structure 108 comprising electrodes on which LED chips 104-1, 104-2, 104-3 are mounted. The LED chips 104-1, 104-2, and 104-3 can emit light 116 in different colors in a first direction into a cavity 106 formed by a color mixer 110. In an embodiment, LED chips 104-1, 104-2, and 104-3 can be one or more of red, green, or blue, or other combinations of colors. The color mixer 110 can include a reflective layer 112 that includes one or more of a specular reflective material or a diffuse reflector material, and the light from the LED chips 104-1, 104-2, and 104-3 can mix in the cavity 106 of the color mixer 110 before exiting the color mixer 110 through gaps 114 formed by the lead frame structure 108 through an aperture 118 in a direction or orientation opposite the orientation originally emitted by the LED chips 104-1, 104-2, and 104-3.

By having the color mixing performed in a cavity 106 that is opposite the side of the final light emission, an advantage is gained in having improved color mixing without a high loss in luminous flux as in current solutions where the color mixing is performed on the same side of the LED chip as the direction in which the final mixed light is emitted.

The cavity 106 can be air filled, have no air (e.g., a vacuum) or be filled with a transparent fill material (e.g., silicone). The reflective layer 112 on the internal surface of the color mixer 110 can include a layer of a diffuse reflective material such as TiO₂ or include a metallic layer to provide specular reflection.

In an embodiment, the aperture 118 of the color mixer 110 can be an opening, or a side of the color mixer 110 that does not include the reflective material 112. In an embodiment, a width of the aperture 118 can be smaller than a maximum width of the color mixer 110. In other embodiments, the width of aperture 118 is substantially equal to a width of the cavity 106 of the color mixer 110 adjacent to the aperture 118.

In the embodiment shown in FIG. 1, the color mixer 110 is domelike or semispherical. In other embodiments, such as in FIG. 2, the color mixer 110 can be conical or triangular.

It is to be appreciated that when stating that the orientation of the light 116 emitted from the LED package 100 is opposite that of the orientation of the light 116 emitted by the LED chips 104-1, 104-2, and 104-3, that “opposite” is referring to the vector average of the light 116 emitted by the LED chips. From the perspective of FIG. 1 for example, the light 116 emitted by the LED chips is in a variety of directions, but the average vector is upwards, whereas the average vector emitted by the light from the LED package through the aperture 118 is downwards. Another way to characterize the light emission orientations is that the LED chips 104-1, 104-2, and 104-3 emit light 116 in a first direction away from a first surface of the lead frame structure 108 on which the LED chips 104-1, 104-2, and 104-3 are mounted, and the light 116 emitted from the LED package, after passing through the gaps 114 and the aperture 118 is in a second direction away from a second surface of the lead frame structure 108, wherein the second surface of the lead frame structure is opposite the first surface.

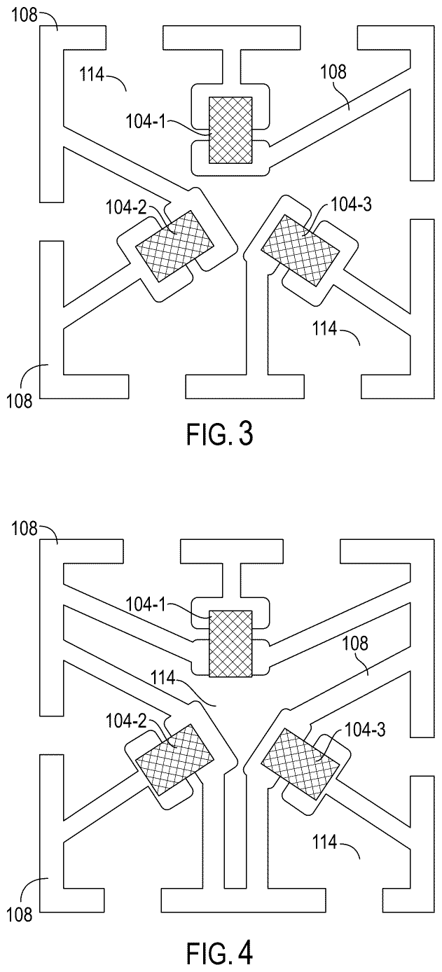

It is also to be appreciated that the separate electrodes of the lead frame structure 108 in FIG. 1 are not floating, and disconnected from the housing or each other, but they are depicted this way in order to more clearly show the gaps 114 through which the light 116 passes. In FIGS. 3 and 4, top down views of the lead frame structure 108 are shown which more clearly show how the electrodes of the lead frame structure 108 are connected to each other.

It is to be appreciated that in FIGS. 1 and 2, the housing 102 shape defines the shape of the color mixer 110, in other embodiments, the shape of the housing 102 maybe distinct from the shape of the color mixer 110, where the color mixer 110 is formed by silicone or other transparent material, with the reflective layer 112 on the outside edge of the silicone or transparent material, and that the color mixer 110 is inside a cavity formed by the housing 102.

FIGS. 3 and 4 are top-down views of a lead frame structure 108 with separate electrodes (FIG. 3) or with a common electrode (FIG. 4) with a plurality of LED chips 104-1, 104-2, and 104-3 according to embodiments of the present disclosure. The LED chips 104-1, 104-2, and 104-3 are illustrated with a flip-chip arrangement to the lead frame structure 108. This arrangement avoids positioning wire bonds in the light path that could contribute to light-absorption. It is to be appreciated that the principles described would also be applicable for improved color mixing for LED chip structures that do include wire bonds to the lead frame structure 108.

In the embodiment in FIG. 3, each of the electrodes of the lead frame structure 108 are separate from each other, and can be controlled independently, whereas in FIG. 4, one of the electrodes for each of the LED chips 104-1, 104-2, and 104-3 can be commonly controlled, whereas the opposing electrode for each of the LED chips 104-1, 104-2, and 104-3 is separate and independent controlled.

As is seen more clearly in FIGS. 3 and 4 relative to FIGS. 1 and 2, there can be gaps 114 between electrodes and between the LED chips 104-1, 104-2, and 104-3 through which the light 116 can pass through after mixing in the color mixer 110.

It is to be appreciated that while the general shape of the lead frame structures in FIGS. 3 and 4 are square, in other embodiments, they could be rectangular, circular, oval, or some other shape. Additionally, the LED chips 104-1, 104-2, and 104-3 are arrayed with rotational symmetry around the center of the lead frame structure 108, but in other embodiments, the LED chips 104-1, 104-2, and 104-3 can be arrayed side by side, or end to end, or any other orientation.

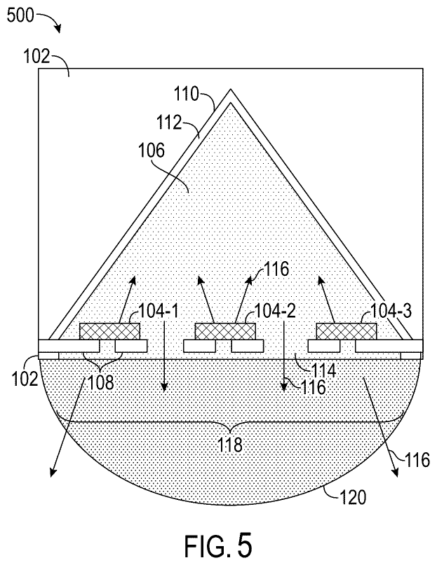

FIG. 5 is a cross-sectional view of the LED package of FIG. 2 with an additional lens according to an embodiment of the present disclosure.

The LED package 500 in FIG. 5 is similar to that shown in FIG. 2, except a dome or lens 120 is placed over the aperture 118 and is mounted to the housing 102 and/or the color mixer 110. The lens 120 may comprise silicone, glass, epoxy, or other materials that are light-transparent to light emitted by the LED chips 104-1, 104-2, and 104-3. Light 116 passing through the aperture 118 enters the lens 120 and is further focused or directed in order to achieve the desired light emission profile. The lens 120 is shown as being plano-convex in FIG. 5, but in other embodiments could have an outer surface that is concave, flat, or both convex and concave depending on the desired light emission profile.

In an embodiment, the lens 120 can be mounted by an adhesive to the housing 102. In other embodiments, the lens 120 can be mounted directly to the color mixer 110, in embodiments where the cavity 106 of the color mixer is silicone. There can be an airgap between the color mixer 110 and the dome 120 in some embodiments, and in other embodiments, there is no air gap.

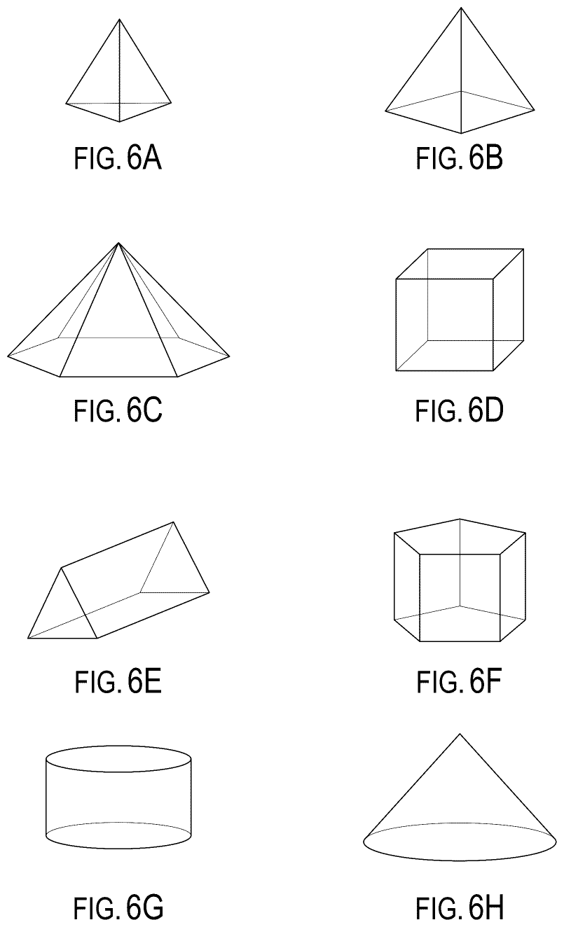

FIG. 6A-H are views of different shapes of color mixers according to embodiments of the present disclosure. The various shapes of color mixers depicted in FIGS. 6A-6H may be implemented in any of the structures illustrated with respect to FIGS. 1-5. The shapes shown are merely exemplary, and other shapes are possible in other embodiments. It is also to be appreciated that variations of the shapes are possible, such as for example, the shapes shown in FIGS. 6A, 6B, 6C, and 6H have pointed peaks, in other embodiments, the tops of the shapes can be flat, without the points.

FIG. 6A shows a color mixer 110 that is a tetrahedron (triangular pyramid), while FIG. 6B shows a similar color mixer 110 that has a square base and is a pyramid. FIG. 6C shows a color mixer 110 that is also pyramid shaped but has a hexagonal base.

FIG. 6D shows a cuboid color mixer 110. This particular cuboid color mixer 110 is substantially cube shaped, but in other embodiments, one or more edges can be longer, giving an elongated rectangular cuboid shape.

FIG. 6E shows a triangular prism color mixer 110, while FIG. 6F shows a hexagonal prism color mixer 110. Other prism type shapes are possible as well in other embodiments, such as a pentagonal prism, dodecahedron, or icosahedron. FIG. 6G shows a cylindrical color mixer 110, but spherical and ellipsoid color mixers 110 are also possible in other embodiments. FIG. 6H depicts a conical color mixer 110.

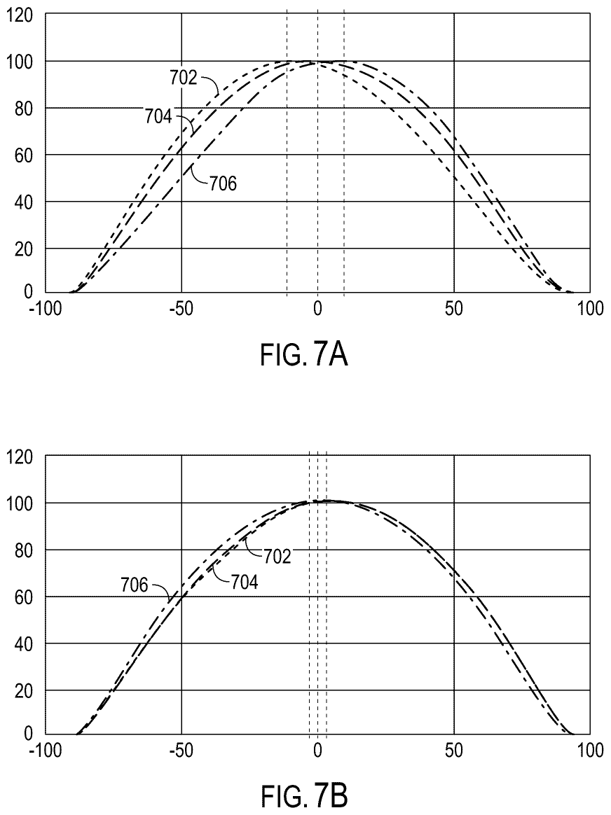

FIGS. 7A and 7B are graphs showing the intensity of different colors at different viewing angles for a state of the art color mixer and the color mixer as disclosed herein according to principles of the present disclosure.

For example, as shown in FIG. 7A, the peak intensity (as shown by the vertical dashed lines) of the red light 702 emitted by the state of the art color mixer peaks at around −10 degrees off axis, the green light 704 peaks at 0 degrees, and the blue light 706 peaks at around +10 degrees off axis. By comparison, in FIG. 7B, which depicts the intensity of red green and blue light emitted by the LED device as disclosed by an LED package with the color mixer as disclosed herein, the peak intensities of the colors are closer together, providing a more uniform color mixing.

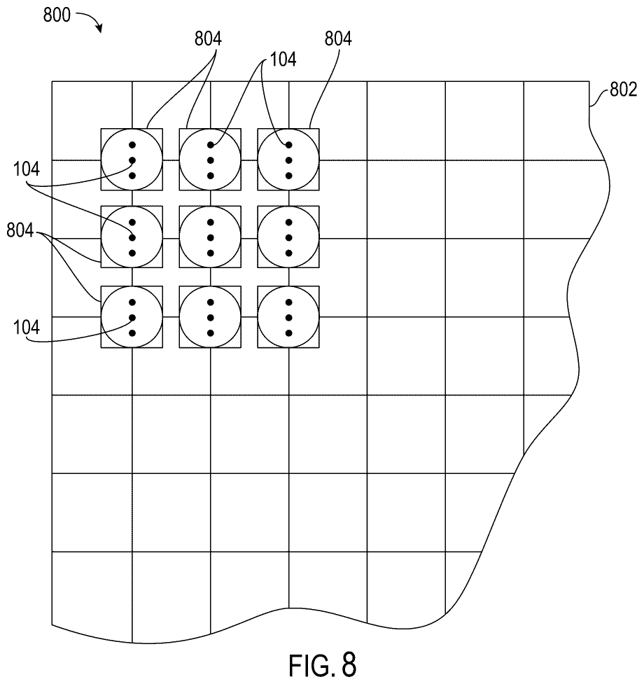

FIG. 8 is a schematic diagram of a portion of an LED device, such as a display screen including a large number of LED packages according to principles of the present disclosure.

FIG. 8 is a schematic diagram of a portion of an LED device 800, such as a display screen, for example, an indoor and/or outdoor screen comprising, in general terms, a display panel including a driver printed circuit board (PCB) 802 carrying a large number of surface-mount devices (SMDs) 804 arranged in rows and columns, each SMD 804 defining a pixel. Each SMD 804 could be for example LED packages with integral color mixers according to any of the embodiments described above with respect to FIGS. 1 to 6H. Additionally, each SMD 804 may represent a multiple chip embodiment of different colors, such as red-green-blue, for forming an LED pixel. With the integral color mixers for each SMD 804 according to the principles described herein, the LED device 800 may exhibit improved overall color uniformity across a variety of viewing angles. The SMDs 804 are electrically connected to traces or pads on the PCB 702 to respond to appropriate electrical signal processing and driver circuitry (not shown). While FIG. 8 depicts the LED chips 104 (e.g., 104-1, 104-2, and 104-3) in a linear arrangement within each LED package for the SMDs 804, in other embodiments, the LED chips 104 may be arranged in different configurations.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) package, comprising:
a lead frame;
a plurality of LED chips mounted on a first side of the lead frame that emit light in a first orientation; and
a color mixer comprising a cavity in which the light emitted by the plurality of LED chips mixes, wherein the light is emitted from the color mixer via an aperture proximate to a second side of the lead frame opposite the first side in a second orientation opposite the first orientation.

2. The LED package of claim 1, wherein the light emitted from the color mixer passes through gaps in the lead frame.

3. The LED package of claim 1, further comprising a housing in which the lead frame, the plurality of LED chips and the color mixer are housed.

4. The LED package of claim 3, further comprising a lens fixed to the housing that receives light from the aperture and emits the light after passing through the lens.

5. The LED package of claim 1, wherein a width of the aperture is equal to a width of the cavity of the color mixer.

6. The LED package of claim 1, wherein the color mixer comprises a reflective layer.

7. The LED package of claim 1, wherein the reflective layer comprises at least one of a specular reflective layer or a diffuse reflective layer.

8. The LED package of claim 1, wherein the color mixer is in a shape that is at least one of conical, prismatic, pyramidical, spherical, elliptical, cuboid, or cylindrical.

9. The LED package of claim 1, wherein the cavity comprises at least one of air, vacuum, or silicone.

10. The LED package of claim 1, wherein the plurality of LED chips comprise at least one red LED chip, at least one blue LED chip, and at least one green LED chip.

11. A light emitting diode (LED) package, comprising:
a housing;
a lead frame that is mounted to the housing;
a plurality of LED chips mounted on a first side of the lead frame that emit light in a first orientation; and
a color mixer mounted within the housing that comprises a cavity surrounded by a reflective layer in which the light emitted by the plurality of LED chips mixes, wherein the light is emitted from the color mixer via an aperture proximate to a second side of the lead frame opposite the first side in a second orientation opposite the first orientation.

12. The LED package of claim 11, wherein the light emitted from the color mixer passes through gaps in the lead frame.

13. The LED package of claim 11, further comprising a lens fixed to the housing that receives light from the aperture and emits the light after passing through the lens.

14. The LED package of claim 11, wherein a width of the aperture is equal to a width of the cavity of the color mixer.

15. The LED package of claim 11, wherein the reflective layer of the color mixer comprises at least one of a specular reflective layer or a diffuse reflective layer.

16. The LED package of claim 11, wherein the color mixer is in a shape that is at least one of conical, prismatic, pyramidical, spherical, elliptical, cuboid, or cylindrical.

17. The LED package of claim 11, wherein the cavity comprises at least one of air, vacuum, or silicone.

18. The LED package of claim 11, wherein the plurality of LED chips comprise at least one red LED chip, at least one blue LED chip, and at least one green LED chip.

19. A lighting device comprising:
a board; and
a light-emitting diode (LED) package mounted on the board, the LED package comprising:
a lead frame;
a plurality of LED chips mounted on a first side of the lead frame that emit light in a first orientation; and
a color mixer comprising a cavity in which the light emitted by the plurality of LED chips mixes, wherein the light is emitted from the color mixer via an aperture proximate to a second side of the lead frame opposite the first side in a second orientation opposite the first orientation.

20. The lighting device of claim 19, wherein the reflective layer of the color mixer comprises at least one of a specular reflective layer or a diffuse reflective layer.
